(19) United States
(12) Patent Application Publication
(10) Pub. No.: US 2013/0220794 A1
(43) Pub. Date: Aug. 29, 2013

(54) APPARATUS AND METHOD FOR MULTI-SOURCE DEPOSITION

(71) Applicant: Dynavac, (US)

(72) Inventor: Gary S. ASH, Dartmouth, MA (US)

(73) Assignee: Dynavac, Hingham, MA (US)

(21) Appl. No.: 13/772,968

(22) Filed: Feb. 21, 2013

Related U.S. Application Data
(60) Provisional application No. 61/602,298, filed on Feb. 23, 2012.

(51) Int. Cl. C23C 14/34

(52) U.S. Cl. CPC C23C 14/3492
USPC 204/192.1; 204/298.28; 204/298.16; 204/298.09; 204/298.04

(57) ABSTRACT

Exemplary embodiments provide a multi-source deposition method and apparatus for the provision of coatings within relatively tight tolerances. An apparatus may be provided including control circuitry and a plurality of deposition sources for coating a substrate. The sources may be disposed a selectable distance away from the substrate and/or may be tilted at a selected angle. The control circuitry may utilize information indicative of an emission pattern associated with each of the sources to adjust a power to each of the sources during coating of the substrate. By rotating the substrate relative to the sources and/or controlling parameters such as source height, tilt angle, and source power, a substantially uniform coating thickness may be achieved on the substrate.

### RELATED APPLICATIONS

The present application claims priority to U.S. Provisional Patent Application Ser. No. 61/602,298, filed Feb. 23, 2012. The contents of the aforementioned application are hereby incorporated by reference.

### TECHNICAL FIELD

Exemplary embodiments generally relate to the application of thin film coatings to materials and, more particularly, relate to the provision of a coating having a substantially uniform thickness using multiple sources.

### BACKGROUND

In a number of applications, a substrate must be coated with a film, such as a relatively thin film coating. Such applications include, for example, the coating of architectural glass, the coating of solar collector mirrors, and the coating of telescope minors.

The application of thin film coatings may be accomplished via any of a number of techniques. Some techniques, including sputtering techniques, utilize a source to eject a coating material onto a substrate. As shown in FIG. 11, the coating material 102 may typically be ejected from a single source 104 that is set above the substrate 106 at a known distance. The coating material may therefore form a coating layer 108 on the substrate 106.

One common problem that may arise from this arrangement is that the coating material may tend to build up more heavily near a center of the substrate's coated area, at the edge, or at some other location on the substrate. Meanwhile, the coating material may end up being thinner at edges of the substrate's coated area. This non-uniform distribution may be caused by a number of factors, including a limited ability of the source 104 to evenly distribute the coating material 102, the age of the source 104 (as older sources may become clogged or may lose power over time, thereby developing “hot spots” in which the source 104 deposits relatively more coating material 104), and environmental conditions in the location in which the sputtering occurs, among other possibilities.

To combat this problem, masks are sometimes employed to control the application of the coating and maintain coating thickness in predetermined wedge-shaped slices or zones. A source or sources may be moved and the mask may be adjusted during coating. However, this method has poor reliability, is difficult to adjust correctly and generates stripes of non-uniform thickness between the coated zones and at the mask starting/ending position.

Some applications for coating techniques, particularly in sensitive fields such as scientific research, may require relatively tight tolerances in the allowable variation in coating thickness across the substrate. The inherent nature of the sources may make providing end products meeting these tight tolerances a challenge. As the size of the substrate to be coated increases, the magnitude of that challenge may also increase. Meanwhile, substrates having irregular shapes may also present unique challenges.

### SUMMARY

Exemplary embodiments may provide a multi-source deposition method and apparatus for the provision of coatings within relatively tight tolerances.

According to an exemplary embodiment, an apparatus may be provided including a deposition chamber or housing, a plurality of deposition sources, and control circuitry. The deposition chamber or housing may be configured to receive a substrate. The substrate may be rotatable relative to the plurality of deposition sources. For example, either the substrate, or the sources, or both, may be rotatable with respect to each other. Due to the relative rotation of the substrate with respect to the deposition sources, a coating of substantially uniform thickness may be provided on the substrate. Furthermore, because multiple deposition sources may be used, relatively small sources be used may cover the entire surface of the substrate.

The deposition sources may be disposed a selectable distance away from the substrate and/or may be tilted at a selected angle. The control circuitry may utilize information indicative of an emission pattern associated with each of the sources to adjust a power to each of the sources during coating of the substrate.

Accordingly, a coating material may be deposited on the substrate by the sources. By rotating the sources and/or the substrate relative to each other and varying the power of the sources, the tilt angle of the sources, the distance between the sources and the substrate, and/or environmental parameters in the deposition chamber, a coating of substantially uniform thickness may be achieved.

In some embodiments, the sources may be provided on a gantry elevated at the selectable distance above the substrate. The substrate may be rotatable in a continuous or oscillatory fashion relative to the sources. Alternatively or in addition, the gantry may be rotatable in a continuous or oscillatory fashion relative to the substrate.

The control circuitry may be configured to control rotation of the substrate or the sources, a tilt angle of one or more of the sources, a height of the substrate and/or sources, and control environmental parameters in the deposition chamber.

The sources may include, for example, magnetron sputter sources, electron beam evaporation sources, thermally heated sources, chemical vapor deposition sources, or ion beam deposition sources.

According to another exemplary embodiment, a method may include receiving information indicative of an emission pattern associated with each of a plurality of deposition sources disposed a selectable distance away from a substrate to be coated. Furthermore, information indicative of relative rotation between the substrate and the sources may also be received. Based on the received information indicative of the emission pattern associated with each of the sources and the received information indicative of the relative rotation, processing circuitry may determine a power level to be applied to each of the sources during coating of the substrate in order to achieve a predetermined coating shape, such as a substantially uniform coating.

In some embodiments, the method may be embodied as non-transitory electronic-device-executable instructions that, when executed by processing logic, cause the processing logic to carry out the method.

### BRIEF DESCRIPTION OF THE DRAWINGS

Having thus described the invention in general terms, reference will now be made to the accompanying drawings, which are not necessarily drawn to scale, and wherein:

FIG. 1 depicts an exemplary coated substrate prepared according to exemplary embodiments of the present invention;

FIG. 2 depicts one exemplary embodiment in which an exemplary substrate is coated by three exemplary magnetron sources.

FIG. 3 is a graph depicting an exemplary coating thickness on a substrate produced using an apparatus similar to the exemplary embodiment of FIG. 2.

FIGS. 4A and 4B depict an exemplary gantry that may be employed to distribute sources relative to a substrate according to exemplary embodiment;

FIG. 5 illustrates a conceptual diagram of one example deposition chamber according to an example embodiment;

FIG. 6 illustrates a conceptual diagram of an alternative structure for providing a deposition chamber according to an example embodiment;

FIG. 7 illustrates a method of employing multiple source deposition according to exemplary embodiments.

FIG. 8 illustrates a block diagram of an apparatus for controlling deposition of a coating material within a deposition chamber according to exemplary embodiments;

FIG. 9 is a graph depicting the thickness of an exemplary coating on a substrate due to each of six magnetron sources when applied using an apparatus according to an exemplary embodiment;

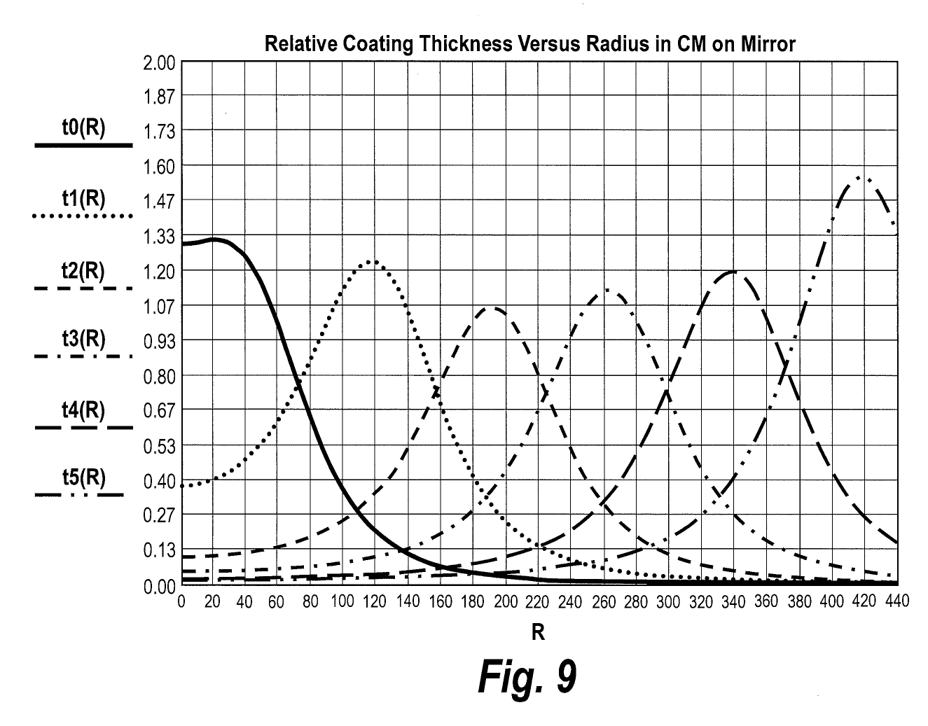

FIG. 10 is a graph depicting an exemplary overall coating thickness according to the exemplary embodiment depicted in FIG. 9; and

FIG. 11 illustrates a side view of material deposition on a substrate during a conventional coating process using a single source.

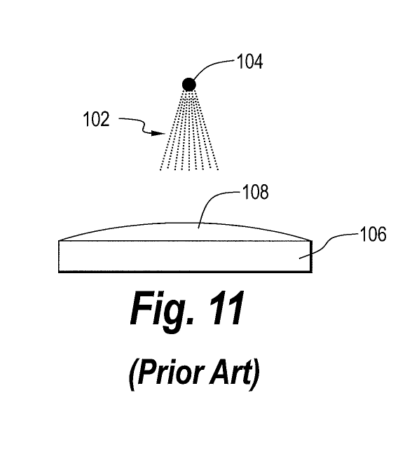

Like reference numerals refer to like elements throughout.

### DETAILED DESCRIPTION

As indicated above, some embodiments may provide a multi-source deposition method and apparatus for the provision of coatings within relatively tight tolerances (in exemplary embodiments, a coating with a thickness that varies in depth with a tolerance of between about 1% and about 5%). In this regard, exemplary embodiments may enable operators to achieve coating of products within relatively tight tolerances on substrates having a wide range of shapes and sizes.

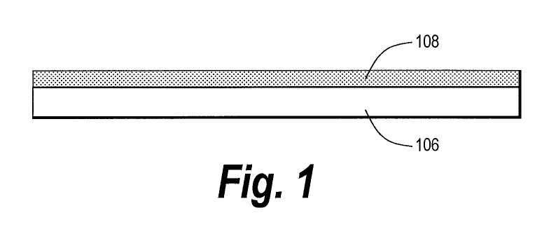

An example of a product prepared according to exemplary embodiments is depicted in FIG. 1. As shown in FIG. 1, a substrate 106 may be coated with a coating material 108 such that the coating material 108 is provided at a substantially uniform thickness across the surface of the substrate 106.

Generally speaking, exemplary embodiments may employ multiple sources for which rotation of the substrate and/or the sources may be provided to reduce the impact of the tendency of substrates to have material buildups occur proximate to a center of their coated areas. The flux of the sources may also be controllable to enable operators to have a tighter control over the results that are achievable (as used herein, “flux” refers to the rate at which a source deposits material on the substrate surface). In some embodiments, spacing between the sources and the substrates and/or the tilt angle of the sources with respect to the substrate may be adjustable to enable control over the size of the coated area for even more control over uniformity. Accordingly, some exemplary embodiments may be well suited for use in connection with relatively large and/or irregular shaped substrates.

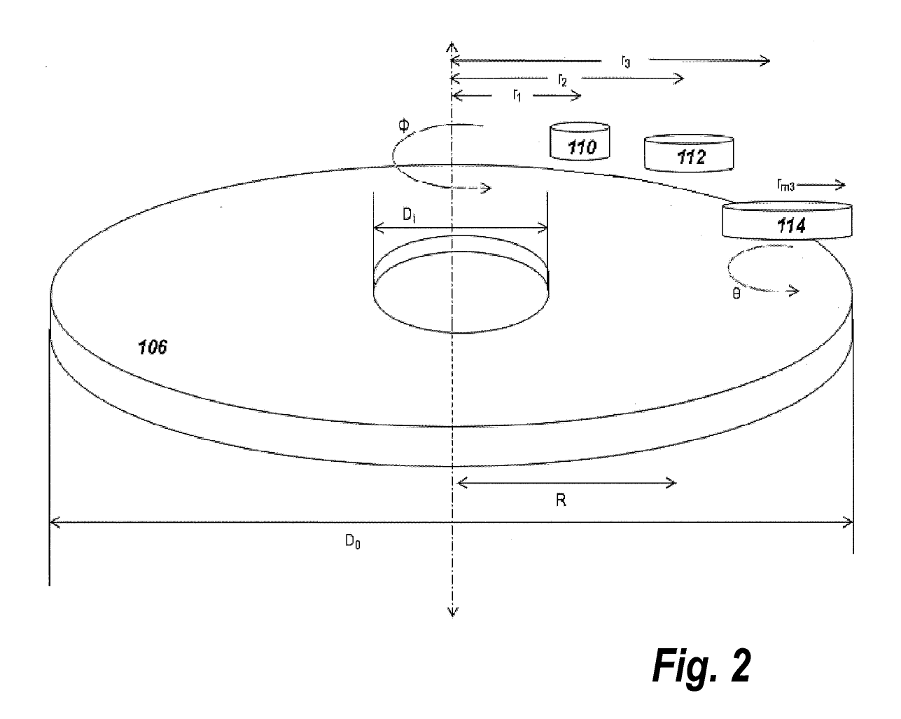

For example, FIG. 2 depicts a general set up for depositing a coating material on a substrate 106. As depicted in FIG. 2, the substrate 106 may be, for example, a round substrate having an opening at the center. Such a substrate 106 may represent, for example, a telescope mirror. The substrate 106 may have an outer diameter D_{O}, representing the diameter of the substrate 106 along an outer circumference, and an inner diameter D_{I}, representing the diameter of the opening at the center of the substrate 106. A value r may represent a distance from the center of a source to a point along the radius of the source. An arbitrary distance away from the center of the substrate 106 (or center of rotation of the substrate 106) may be represented by a value R.

The present invention is not limited to applying coatings the specific shape and size of substrates described in exemplary embodiments herein. One of ordinary skill in the art will recognize that the substrate 106 may be of any shape or size.

A plurality of sources (in this case, three sources 110, 112, 114) may be provided, each at a different radius from the center of the substrate 106. In the example of FIG. 2, the first source 110 is provided at a distance r₁ from the center of the substrate 106, the second source 112 is provided at a second distance r₂ from the center of the substrate 106, and the third source 114 is provided at a third distance r₃ from the center of the substrate, where:

r₁<r₂<r₃

The sources 110, 112, 114 may be round as depicted in FIG. 2, or may take a number of other suitable shapes, such as rectangular sources. If the sources are round, the sources may have a radius of rₘₙ, where n represents the number of the source. In some exemplary embodiments the sources may have varying sizes that remain the same or become gradually larger as the sources move away from the center of the substrate 106, such that:

rₘ₁<rₘ₂<rₘ₃

The substrate and/or set of sources may rotate with respect to each other. The rotation of the substrate may be represented by an angle Φ, while a rotation of each of the sources may be represented by angles θ.

In exemplary embodiments, the relative rotation accomplished by sources or by the substrate is exactly one or more rotations when a single set of sources is used. To reduce the total amount of angular rotation, some number m of identical sets of sources may be used so that the required rotation is 360/m degrees or an integral multiple thereof.

The thickness of the coating at a distance R from the center of the substrate due to a particular source n may then be given by Equation 1:

$$tn ( R ) := {\int }_{0}^{2 π} {\int }_{0}^{rmn} {\int }_{0}^{2 π} \frac{{( hn )}^{2} \cdot r \cdot pn}{{[ {( hn )}^{2} + [ \begin{matrix}{( R cos ( Φ ) - ( rn + r \cdot cos ( θ ) ) )}^{2} + \\ {( R \cdot sin ( Φ ) - r sin ( θ ) )}^{2}\end{matrix} ] ]}^{2}} d θ d r d Φ \qquad Equation 1$$

where pn is the power density of the source and hn is the height of the source above the top surface of the substrate.

Equation 1 is an exemplary thickness equation, wherein: the outer integral goes around the substrate at a radius=R, angle Φ; the middle integral goes from the center of the source to its outer radius, and the inner integral goes around the source axis, angle θ. One of ordinary skill in the art will recognize that Equation 1 is intended to be exemplary, and that further derivations for coating thickness may be possible for different sources.

The total thickness t(R) of the coating at a distance R from the center of the substrate due to all of a plurality N of sources may be given by Equation 2:

t(R):=Σ₀^{N}tn(R) Equation 2

The relative thickness trel(R) of the coating at a distance R from the center of the substrate, normalized to a point on the substrate (D_{I} in this example) is given by equation 3:

$$tre 1 ( R ) := \frac{t ( R )}{t ( {D}_{I} )} \qquad Equation 3$$

One of ordinary skill in the art will recognize that the relative thickness trel(R) may be calculated with respect to any point on the substrate, and need not necessarily be calculated with respect to D_{I}.

By establishing the parameters hn, rn, pn, rmn, Φ, and θ such that trel(R) is maintained within a predetermined tolerance from 1 (in one embodiment, between 0.95 and 1.05) for each value of R, an apparatus may be set up to coat a substrate with a substantially uniform coating thickness.

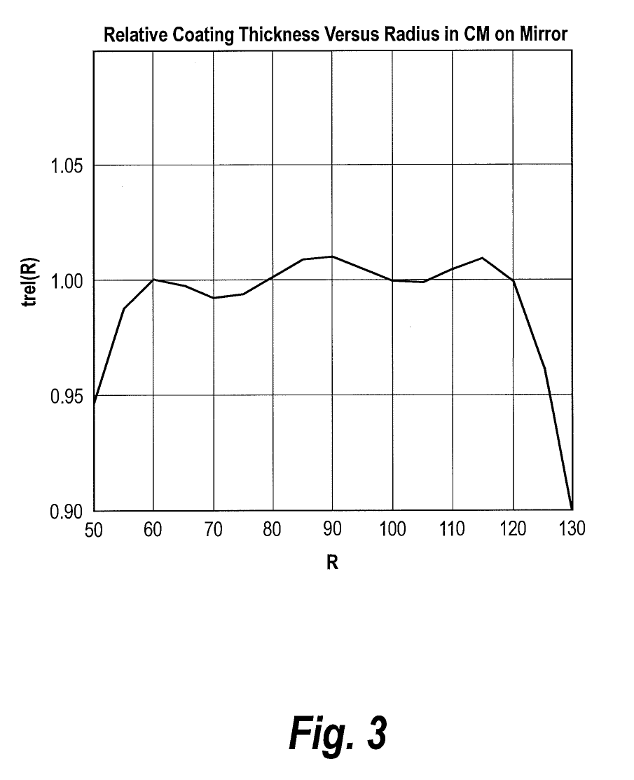

For example, FIG. 3 illustrates one example showing the thickness of a coating material over a substrate 106 applied using an apparatus similar to the one depicted in FIG. 2. In this example, the thickness uniformity shown was achieved across a substrate with an outer radius of 125 cm and an inner radius of 55 cm using three magnetron sources.

As shown in FIG. 3, one or more peaks may be present in the thickness of the coating. These peaks may represent the area in which each of the sources deposit the most coating (e.g., the location where the flux from each individual source is the greatest). Nonetheless, as can be seen in FIG. 3, between the radius values of 55 cm and 125 cm, the relative coating thickness varies only slightly, from about 0.97 at a minimum to about 1.01 at a maximum.

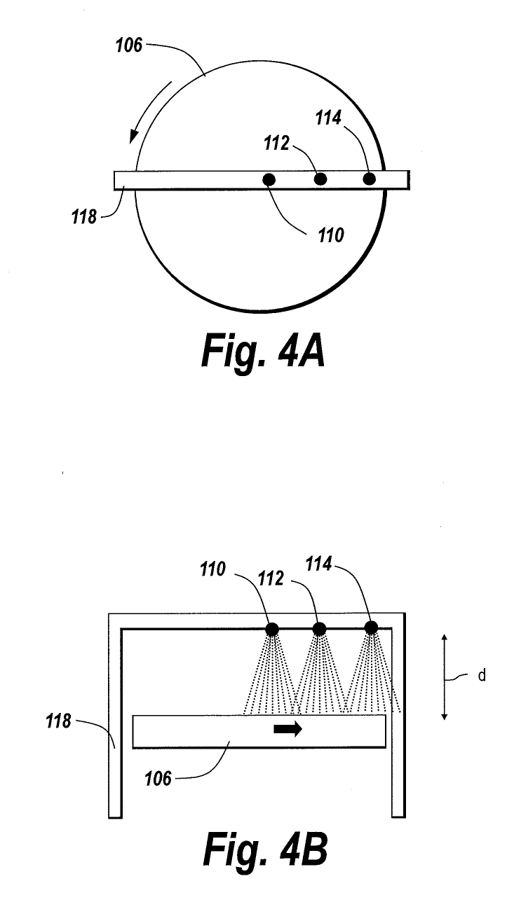

In order to deposit the coating in a substantially uniform manner, the sources 110, 112, 114 may be mounted on a structure that allows the sources 110-114 to be located a selectable distance from the substrate 106 and from each other. For example, FIGS. 4A and 4B depict an exemplary gantry 118 for mounting a plurality of sources 110-114.

The gantry 118 may be a structure, housing, or platform from which the sources may deposit the coating material on the substrate 106. The exemplary gantry 118 may be employed to distribute sources relative to a substrate according to an exemplary embodiment. FIG. 4A illustrates a top view of the gantry 118 and FIG. 4B illustrates a side view of the gantry 118.

A plurality of sources 110-114 may be present on the gantry. The gantry 118 may be a structure, such as a platform mounted on a series of supports or a housing, for maintaining the sources 110-114 in a predetermined configuration.

Each of the sources may be, for example, a head comprising a one or more mechanisms for depositing a plurality of streams of the coating onto the substrate. Examples of sources include, but are not limited to, magnetron sputter sources, electron beam evaporation sources, thermally heated sources, chemical vapor deposition sources, or ion beam deposition sources. The use of multiple sources may be useful in generating a more uniform thickness on the substrate 106 than can be obtained by using only a single source.

Sources of different types may have different flux emission patterns. For example, a small filament source may be considered a “point source” which emits into a full sphere. At any angle from its center point, the flux may be constant for a fixed radius. Other evaporation sources, such as electron beam sources which produce an emission area of (e.g.) 25 mm diameter or more may be considered “extended area sources” with flux emitted into only a hemisphere and the flux varying with the cosine of the angle to the emission surface normal. In some cases, the flux variation may be as cosine^{x} with x having a typical range of 1.0 to 2.0. A magnetron sputter source may be a (relatively) very large area source with emission into a hemisphere and angular distribution of flux following a cosine^{x} pattern with x normally in the range of 0.5 to 1.5. Additionally, the flux intensity over the area of the emitting surface may be non-uniform due to the magnetic field pattern built into the magnetron. Magnetrons may be made in round, rectangular, or other arbitrary shapes.

In spite of these variations, exemplary embodiments provide substantial uniformity using any of these types, and other types, of sources.

In exemplary embodiments, the sources 110-114 may each be present at different distances from the center of the gantry or substrate to be coated. In other words, the sources may each be distributed at different radii from the center of the substrate.

In some embodiments, source placement may be determined based on the use of n sources with approximate locations on a substrate holder (e.g., gantry) of radius R at locations r₁=R/(n*2), r₂=R*3/(n*2), r₃=R*5/(n*2), etc., with source height approximately equal to R. Positions, heights, and power levels may then be adjusted to give desirable uniformity. However, some embodiments may only employ source tilting for outer sources or even for only the outer most source. In some embodiments, there may not be complete freedom to make height=R for very large substrates, because there may be limits to the “mean free path” of gas molecules at sputter or evaporation pressures within the chamber. As such, there may be a mathematical method to determine source locations. However, some embodiments may further benefit from some fine manual adjustment in order to achieve a desirable uniformity.

The substrate 106 may be rotatable (in any direction) beneath the gantry 118 to improve uniformity of coating. For example, the gantry 118 may be provided with a rotation mechanism, such as a spinning support, turntable, tray, pedestal, support, or any other structure capable of supporting the substrate 106, which allows for rotation of the substrate 106 with respect to the sources 110, 112, 114. The rotation mechanism may be located below the substrate 106.

It should be appreciated that the sources 110, 112, 114 could be disposed on either or both sides of the axis of rotation of the substrate or even on the axis of rotation. It should be further be noted that the gantry 118 itself may be rotated, or both the gantry 118 and the substrate 106 may be rotated in alternative embodiments.

By providing relative motion between the sources 110, 112, 114 and the substrate 106 (e.g., via rotation of either or both of the substrate and the sources, the overall profile of the coating material depth may be more uniformly provided.

Adjusting the tilt of a source may provide an additional degree of freedom. Thus, the gantry 118 may allow the substrate 106 to be tilted with respect to the plane of the sources 110, 112, 114. For example, the gantry 118 may include a motor, actuator, pivot head, or other mechanism for tilting one or more of the sources 110, 112, 114 with respect to the substrate. Additional adjustments in the thickness of the deposited coating across the coated area may be obtained by tilting the source so that the main axis of the emission plume is no longer perpendicular to the substrate. Such adjustments in tilt angle of the sources may increase the efficiency of capture by the substrate of the material originating from the sources, increasing the economic benefit when source materials are expensive and reducing the time needed to deposit a coating.

Additionally, the rate of deposition (e.g., the flux) from any individual source may be adjustable. In the case of a sputter source, the rate is linearly dependent on the applied power. For evaporation sources, the rate follows the vapor pressure versus temperature characteristic for the material being evaporated. Generally, the rate of deposition increases as the square of the radius of the substrate for relative motion of the sources and substrate. It will be understood by those familiar with the art that the deposition rates of chemical vapor deposition sources and other types of sources can also be controlled by adjustment of process parameters. The arrangement of the sources and the applied power is intended to produce the intended variation of rate with substrate radius.

A height h between the substrate 106 and one or more of the sources 110, 112, 114 may be varied. For example, the gantry 118 may include an extension mechanism, such as a motor, actuator, or other mechanism for raising and lowering all of the sources 110, 112, 114, 116 with respect to the substrate 106. Alternatively or in addition, the gantry 118 may include individual extension mechanisms for one or more of the sources 110, 112, 114 in order to move a single one of, or a combination that is less than all of, the sources 110, 112, 114.

The height h between the sources and the substrate 210 may impact deposition characteristics. For example, generally speaking, a sputter source has a relative flux rate that decreases as the cosine of the angle with respect to the surface normal increases. Thus, for example, there may be less coating depth achieved near edges of a coated area and more coating depth near a center of the coated area, as previously shown in FIG. 1. The degree of difference in thicknesses may be impacted, at least in part, by the height h.

The height h may be relatively large compared to the dimensions of the sources (e.g. the diameter or length of a magnetron or emission area of a thermal or electron beam evaporation source). This size difference enables the calculation of “far field” deposition patterns and reduces the dependency on the actual size or shape of the emitting area. Furthermore, this size difference also may reduce the number of sources needed to achieve substantial uniformity in coating thickness.

One of ordinary skill in the art will recognize that the embodiments depicted in FIGS. 2-4B are exemplary, and a deposition apparatus suitable for use with the present invention may be provided with a plurality of sources which may include more or fewer than the exemplary embodiments of FIGS. 2-4B.

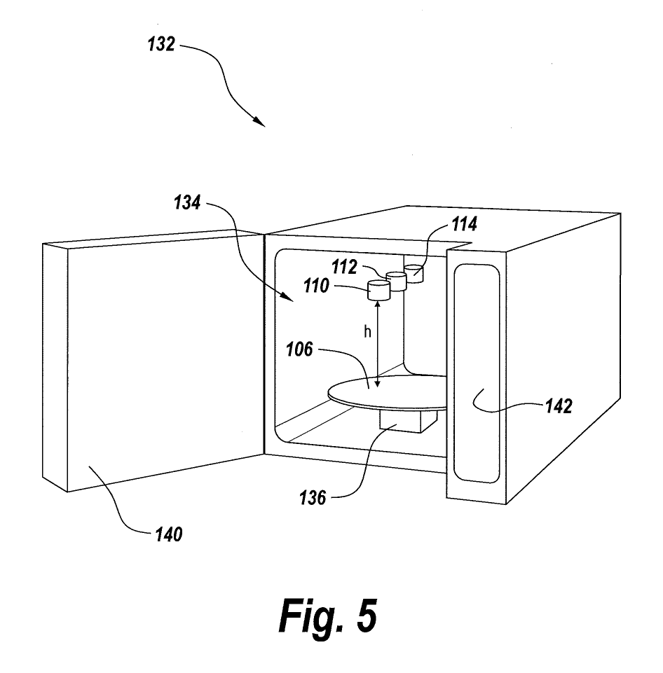

FIG. 5 depicts a further exemplary embodiment including a deposition chamber 132. FIG. 5 illustrates a conceptual diagram of one example chamber. However, it should be appreciated that the chamber 132 of FIG. 5 is not necessarily drawn to scale, nor are all of the components thereof necessarily illustrated.

As shown in FIG. 5, the chamber 132 may include a cavity 134 into which a substrate 106 may be placed for coating. Although a round substrate is shown in FIG. 5, it should be appreciated that the substrate 106 may have any desirable shape and/or size. The substrate 106 may be placed on holder 136, which may take the form of a plate, turntable, tray, pedestal, or any other structure capable of supporting the substrate 106. The holder 136 may have any suitable size and/or shape and may be rotatable in some embodiments. When the holder 136 rotates, the rotation may be accomplished relative to a center of the substrate 106. However, rotation need not necessarily be centered around the geometric center of the substrate 106 in some embodiments. Furthermore, in some embodiments the holder 106 may be the bottom of the cavity 134, and may not rotate at all, if relative rotation between the sources and substrate are provided by some other means. It is also understood that a plurality of substrates of differing shape and size can be placed on a substrate holder 134.

In one embodiment, the chamber 132 may further include a plurality of sources (e.g., first source 110, second source 112, third source 114, etc.). Each of the sources may be a deposition source that is capable of depositing material (e.g., via sputtering, evaporation, chemical vapor deposition, ion beam deposition or other deposition techniques) in a controlled fashion to a target area. For example, the sources may be targets on sputter magnetrons spaced at different radial distances from the center of a part to be coated. The targets may be, for example, round, rectangular, or any other suitable shape. Alternatively, the sources may be electron beam evaporation sources or thermally heated sources. The sources may be suspended from a ceiling of the cavity 134. However, in some embodiments, the sources may be suspended from a gantry, pillars, or other structures.

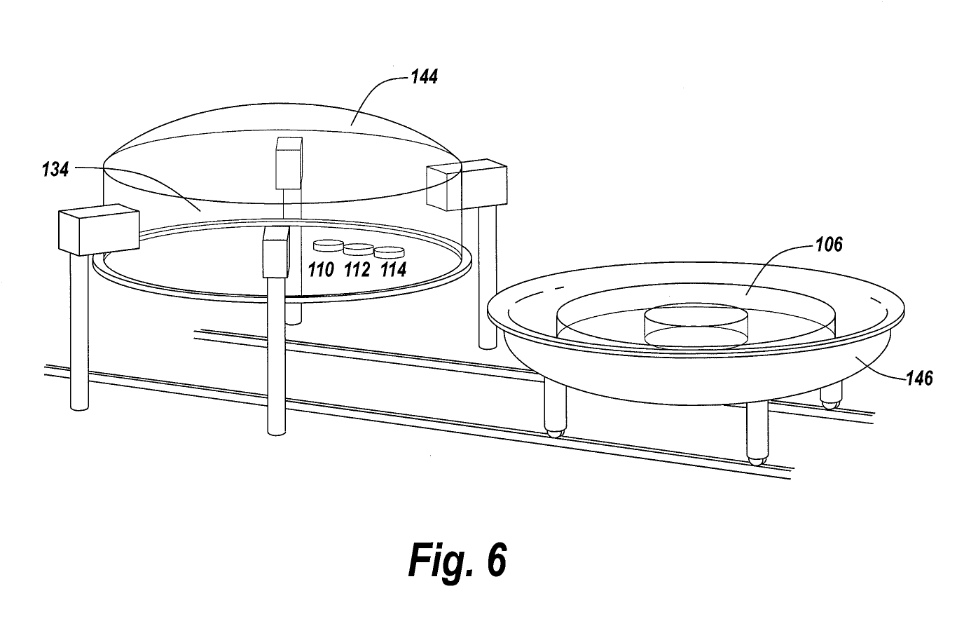

It should be appreciated that although three sources are shown in FIG. 5, any number of sources could be used in alternative exemplary embodiments. Thus, the three sources shown in FIG. 6 are provided to illustrate the potential for multiplicity in relation to the number of sources provided. However, more or fewer sources could be employed in other example embodiments.

It should also be appreciated that FIG. 5 illustrates a relatively simple construction in which the substrate 106 sits on the holder 136 to be supported such that a coated area of the substrate 106 lies in a horizontal plane. However, alternative embodiments can hold the substrate 106 in any desirable orientation. In such alternative embodiments, a position and orientation of the sources can also be adjusted accordingly. For sputter sources, gravity plays no role, so a system may be configured to sputter down, up, sideways, or any desirable direction. Evaporation sources are typically subject to the effects of gravity for a molten pool and for granular materials that sublime instead of melting, so the usual direction of evaporation is upward. However, there are baffled evaporation sources to produce flux in a downward or sideward direction, as well as specialized electron beam sources that may be capable of producing flux axes in directions other than straight up. Thus, even an evaporation system may be configured to operate in other orientations.

In an example embodiment, a height h between the sources 110, 112, 114 and the substrate 106 may be adjustable. Adjustment to the magnitude of the height h may be accomplished by raising a height of the holder 136, by lowering a height of the sources 110, 112, 114, or a combination thereof. Thus, in some embodiments, the sources 110, 112, 114 may be suspended from a fixed height, while in other embodiments; the height of the sources 110, 112, 114 may be adjustable. Furthermore, the height of the sources 110, 112, 114 may be either adjusted individually or adjusted in a group. Height adjustments may be performed manually or automatically in different exemplary embodiments. In an exemplary embodiment, based on the height h, a relatively uniform thickness to within about 1% to about 5% error may be achieved over the surface of the substrate 106 by selecting a target diameter for the sources and controlling the applied power for each source in consideration of the radial distance of each source from the axis of rotation of the substrate 106 or the sources.

The chamber 132 may further include a door 140 and a control panel 142. The door 140 may be closeable to seal the cavity 134 during deposition operations. In some embodiments, the cavity 134 may be pressure controlled and/or vacuum sealed. The control panel 142 may provide user interface options for control of the deposition process and various other aspects associated therewith. As such, the control panel 142 may provide the mechanism by which an operator interacts with control circuitry for controlling cavity pressure, substrate temperature, height h, deposition rates or flux (e.g., via cycling power to the sources), rotation speeds (e.g., for source and/or holder 136 rotation), and/or the like. Thus, for example, any pumps, vents, valves, solenoids, or other control features that may be used in connection with operation of the chamber 134 may be controlled via interface with the control panel 142.

It should be noted that although FIG. 5 illustrates one particular structure for the chamber 132, other suitable structures may also be employed. In this regard, for example, rather than employing a box-like structure with a mounted door 140 enabling access to the cavity 134, any other suitable structure may be utilized.

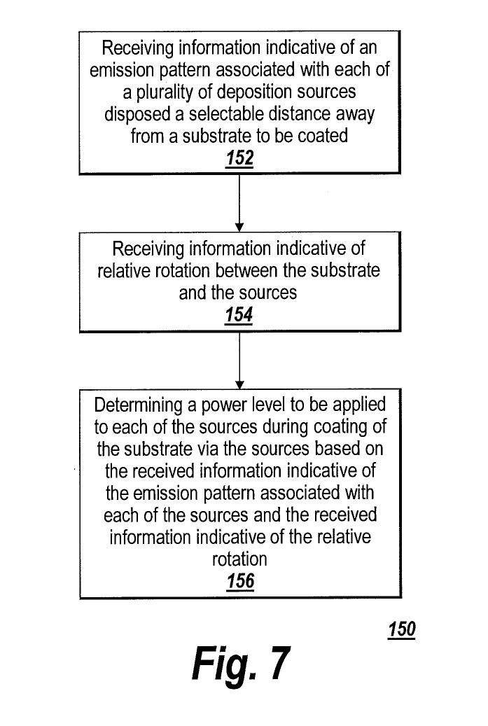

For example, as shown in FIG. 6, a dome 144, or dome-shaped or other structure, may be used to form a cavity 134 in which deposition operations may be performed in accordance with an exemplary embodiment. Moreover, instead of a door 140, the chamber may be accessed via lifting a dome 144 or by moving a movable base portion relative to a substantially fixed dome structure in which the sources may be mounted from a gantry or other structure. In this regard, for example, FIG. 7 shows a moveable base portion 146 on which a substrate 106 may be placed. The base portion 146 may include wheels and/or a track system to enable movement of the base portion 146 to a location at which the base portion 146 may be mated with the dome structure 144 inside which sources 110, 112, 114 may be housed. The substrate 106 and/or the sources 110, 112, 114 may be rotatable by any suitable mechanism. The size and shape of the chamber to be employed may depend, at least to some degree, on the size and shape of the substrate to be coated. Thus, for example, smaller chambers (e.g., like the one in FIG. 6) may be employed when coating relatively small substrates. However, for larger substrates, a larger chamber (e.g., like the one in FIG. 6) may be employed.

The deposition apparatuses of FIGS. 2-6 may apply a coating in accordance with suitable coating methods. For example, FIG. 7 is a flowchart 150 of a method and program product according to an exemplary of the invention. It will be understood that each block of the flowchart, and combinations of blocks in the flowchart, may be implemented by various means, such as hardware, firmware, processor, circuitry and/or other device associated with execution of software including one or more computer program instructions. For example, one or more of the procedures described may be embodied by computer program instructions. In this regard, the computer program instructions which embody the procedures described above may be stored by a memory of a device or another non-transitory computer-readable medium and executed by a processor in the device. As will be appreciated, any such computer program instructions may be loaded onto a computer or other programmable apparatus (e.g., hardware) to produce a machine, such that the instructions which execute on the computer or other programmable apparatus create means for implementing the functions specified in the flowchart block(s). These computer program instructions may also be stored in a computer-readable memory that may direct a computer or other programmable apparatus to function in a particular manner, such that the instructions stored in the computer-readable memory produce an article of manufacture which implements the functions specified in the flowchart block(s). The computer program instructions may also be loaded onto a computer or other programmable apparatus to cause a series of operations to be performed on the computer or other programmable apparatus to produce a computer-implemented process such that the instructions which execute on the computer or other programmable apparatus implement the functions specified in the flowchart block(s).

Accordingly, blocks of the flowchart support combinations of means for performing the specified functions and combinations of operations for performing the specified functions. It will also be understood that one or more blocks of the flowchart, and combinations of blocks in the flowchart, can be implemented by special purpose hardware-based computer systems which perform the specified functions, or combinations of special purpose hardware and computer instructions.

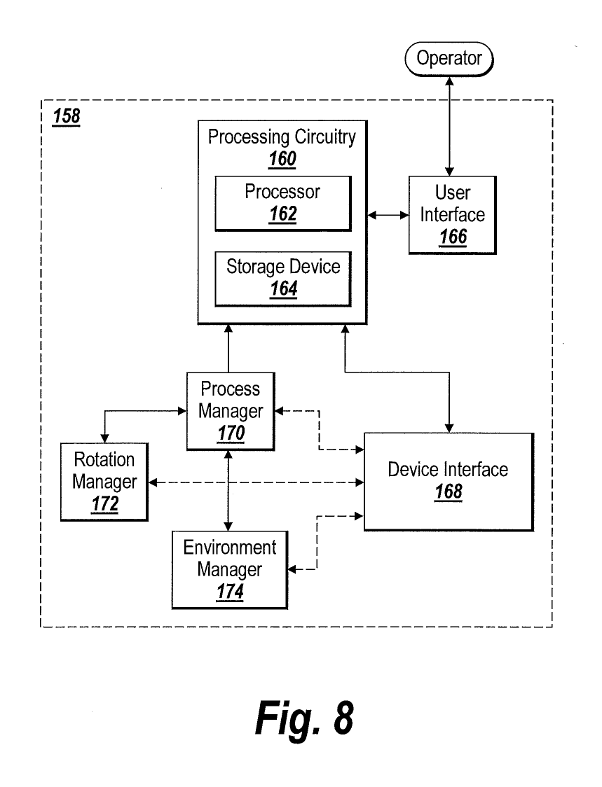

In this regard, a method according to one embodiment of the invention, as shown in FIG. 8, may include a step 152 of receiving information indicative of an emission pattern associated with each of a plurality of deposition sources disposed a selectable distance away from a substrate to be coated. The emission pattern may be, for example, a computer file containing an estimated or simulated pattern that is predicted to occur when a particular source is in operation, or which is measured before or during deposition of the coating material on the substrate. The emission pattern may be determined, for example, by theoretical modeling of the source, by performing a test run of the source before using the source to apply coating material to the substrate (e.g., using a test substrate that measures the emission pattern of the source), or by measuring the emission pattern of the source in operation as the source is applying a coating material to the substrate (e.g., using sensors such as weight sensors, thermal sensors, pressure sensors, etc. to sense the applied coating material), among other possibilities.

The emission pattern may be established with respect to one or more parameters, such as a tilt angle of the source with respect to the substrate, an amount of flux of the source, environmental conditions such as ambient temperature, humidity, or pressure, and other suitable parameters. It should be noted that the selected tilt angle could include no tilt in some embodiments.

The method may further include receiving information indicative of relative rotation between the substrate and the sources at operation 154. The rotation may be achieved for example, by rotating the source, rotating the substrate, or rotating both the source and the substrate. The information indicative of the relative rotation may be provided by one or more sensors measuring a rate of rotation of the substrate, housing, gantry, and/or support structure supporting the substrate. The rate of rotation may further be calculated from other parameters, such as an output of a motor controlling the rate of rotation, among other possibilities.

The method may further include determining, via processing circuitry, a power level to be applied to each of the sources during coating of the substrate via the sources based on the received information indicative of the emission pattern associated with each of the sources and the received information indicative of the relative rotation at operation 156. The power level may be determined by calculating an amount of flux necessary to achieve the desired emission pattern given the other parameters identified at step 152. The amount of flux necessary to achieve the desired emission pattern may be determined through calculation, theoretical modeling, or some other means.

In an exemplary embodiment, an apparatus for performing the method of FIG. 8 above (e.g., the control panel 142) may comprise a suitably-programmed processor configured to perform some or each of the operations (152-156) described above. The processor may, for example, be configured to perform the operations (152-156) by performing hardware implemented logical functions, executing stored instructions, or executing algorithms for performing each of the operations. A block diagram illustrating an example of such an apparatus is depicted in FIG. 8.

An apparatus 158 for provision of control over multi-source deposition is provided. The apparatus 158 may include or otherwise be in communication with processing circuitry 160 that is configured to perform data processing, application execution and other processing and management services according to an example embodiment of the present invention. In one embodiment, the processing circuitry 160 may include a storage device 164 and a processor 162 that may be in communication with or otherwise control a user interface 166 and a device interface 168. As such, the processing circuitry 160 may be embodied as a circuit chip (e.g., an integrated circuit chip) configured (e.g., with hardware, software or a combination of hardware and software) to perform operations described herein. However, in some embodiments, the processing circuitry 160 may be embodied as a portion of a server, computer, laptop, workstation or even one of various mobile computing devices. In situations where the processing circuitry 160 is embodied as a server or at a remotely located computing device, the user interface 166 may be disposed at another device (e.g., at a computer terminal) that may be in communication with the processing circuitry 160 via the device interface 168 and/or a network.

The user interface 166 may be in communication with the processing circuitry 160 to receive an indication of a user input at the user interface 166 and/or to provide an audible, visual, mechanical or other output to the user. As such, the user interface 166 may include, for example, a keyboard, a mouse, a joystick, a display, a touch screen, a microphone, a speaker, a cell phone, or other input/output mechanisms. In embodiments where the apparatus is embodied at a server or other network entity, the user interface 166 may be limited or even eliminated in some cases. Alternatively, as indicated above, the user interface 166 may be remotely located.

The device interface 168 may include one or more interface mechanisms for enabling communication with other devices and/or networks. In some cases, the device interface 168 may be any means such as a device or circuitry embodied in either hardware, software, or a combination of hardware and software that is configured to receive and/or transmit data from/to a network and/or any other device or module in communication with the processing circuitry 160. In this regard, the device interface 168 may include, for example, an antenna (or multiple antennas) and supporting hardware and/or software for enabling communications with a wireless communication network and/or a communication modem or other hardware/software for supporting communication via cable, digital subscriber line (DSL), universal serial bus (USB), Ethernet or other methods. In situations where the device interface 168 communicates with a network, the network may be any of various examples of wireless or wired communication networks such as, for example, data networks like a Local Area Network (LAN), a Metropolitan Area Network (MAN), and/or a Wide Area Network (WAN), such as the Internet.

In an example embodiment, the storage device 164 may include one or more non-transitory storage or memory devices such as, for example, volatile and/or non-volatile memory that may be either fixed or removable. The storage device 164 may be configured to store information, data, applications, instructions or the like for enabling the apparatus to carry out various functions in accordance with example embodiments of the present invention. For example, the storage device 164 may be configured to buffer input data for processing by the processor 162. Additionally or alternatively, the storage device 164 may be configured to store instructions for execution by the processor 162. As yet another alternative, the storage device 164 may include one of a plurality of databases that may store a variety of files, contents or data sets. Among the contents of the storage device 164, applications (e.g., defining deposition processes and corresponding control functions) may be stored for execution by the processor 162 in order to carry out the functionality associated with each respective application.

The processor 162 may be embodied in a number of different ways. For example, the processor 162 may be embodied as various processing means such as a microprocessor or other processing element, a coprocessor, a controller or various other computing or processing devices including integrated circuits such as, for example, an ASIC (application specific integrated circuit), an FPGA (field programmable gate array), a hardware accelerator, or the like. In an example embodiment, the processor 162 may be configured to execute instructions stored in the storage device 164 or otherwise accessible to the processor 162. As such, whether configured by hardware or software methods, or by a combination thereof, the processor 162 may represent an entity (e.g., physically embodied in circuitry) capable of performing operations according to embodiments of the present invention while configured accordingly. Thus, for example, when the processor 162 is embodied as an ASIC, FPGA or the like, the processor 162 may be specifically configured hardware for conducting the operations described herein. Alternatively, as another example, when the processor 162 is embodied as an executor of software instructions, the instructions may specifically configure the processor 162 to perform the operations described herein.

In an exemplary embodiment, the processor 162 (or the processing circuitry 160) may be embodied as, include, or otherwise control a process manager 170, a rotation manager 172 and/or an environment manager 174, each of which may be any means such as a device or circuitry operating in accordance with software or otherwise embodied in hardware or a combination of hardware and software (e.g., processor 162 operating under software control, the processor 162 embodied as an ASIC or FPGA specifically configured to perform the operations described herein, or a combination thereof) thereby configuring the device or circuitry to perform the corresponding functions of the process manager 170, rotation manager 172 and/or environment manager 174, respectively, as described below.

The process manager 170 may be configured to control the rotation manager 172 and/or the environment manager 174 and provide general coordination of processes related to material coating. The process manager 170 may also be configured to control adjustments made to the power applied to the sources. As such, the process manager 170 may control the flux (e.g., the rate of deposition) proportionally. The power provided to each source may be adjusted to produce a sum of fluxes across the substrate surface that produces a relatively uniform coating thickness. For example, the fluxes at portions of the substrate surface over which coated areas from adjacent sources overlap may be summed to achieve a relatively uniform coating thickness.

Due to the relative rotation, it may be desirable to have flux increase along a radial line from the rotation axis to the edge of the substrate proportional to the radius from the axis. The geometric variation in flux may also impact determinations regarding the number of sources to be employed, the distance between the sources and the substrate, applied power, spacing of each source from the central axis, tilt of the source axis relative to the substrate, and area. The area of a sputter source may be decreased if more power is applied to the source, recognizing that there are physical limits to the maximum power per unit area that may be applied without damaging the sputter source. Adjustment of power may also enable fine tuning in order to compensate for deviations in actual flux patterns from theoretical values.

In some cases, the process manager 170 may be configured to access applications and/or instruction sets defining environmental conditions, rotation speeds, source power application, and other controllable parameters for a given coating process. Coating processes may be stored (e.g., in the storage device 354) in association with specific types, sizes and/or shapes of substrates. Thus, for example, the operator may select one or more processes to be employed, or select a program defining processes to be employed, based on the type, size and/or shape of the substrate to be coated.

The rotation manager 172 may be configured to control an electric motor, synchro/servo assembly, or other mechanism capable of causing rotation of the substrate and/or the sources. The rotation provided may be continuous or oscillatory over a full 360 degree range. The environment manager 174 may be configured to provide input to pumps, vents, valves, heaters and/or other components that may enable environmental parameters within the chamber to be controlled.

During operation, test runs may be performed with different power levels and spacing between the sources and targets. In some cases, a rate monitor (e.g., a quartz crystal rate monitor) may be used to measure the sum of the flux from the sources and the flux from any one source by cycling power to the sources. Thus, for example, high value substrates (e.g., large telescope minors and/or the like) may be coated correctly on the first deposition cycle. The capability to use multiple sources in combination with rotation and a dependable expectation regarding the emission pattern (e.g., flux versus angle) may enable the achievement of relatively uniform coating over even substrates of larger size (e.g., greater than 12 to 18 inches and even to 320 inches and beyond, as may be required for large telescope mirrors). Additionally, using multiple sources allows smaller sources to be used, and rotation enables those sources to cover the entire substrate.

Generally speaking, each source is treated as an emitter of flux having a characteristic flux rate versus angle with respect to the normal to the surface of the substrate being coated. Sputter sources may have relative flux rates that decrease with the cosine of the angle with respect to the surface normal. Detailed consideration of flux emission of sputter sources tends to show that the emission is not completely uniform over the source area due to variations in magnetic field strength of the magnetron. However, flux emission may be modeled by a mathematical function of the radius for round sources and a more complex function for sources that are not round (e.g., rectangular sources). The absolute flux from each elemental area of the sources may then be summed as an integral over the substrate taking into account the location of the source from the central axis, height of the source above the substrate, tilt angle of the source axis relative to the substrate, and the relative rotation effect. The result is a triple integral that describes the film thickness over the area of the substrate.

Evaporation sources such as electron beam-heated sources, have an emission versus angle function that describes where the flux goes. For materials that melt easily and evaporate readily, the emission from the melt pool is approximately a cosine function. However, for many materials, the flux versus angle function has a more complex form approximating cosineⁿ, where n may often vary between 1 and 3. The value of n may also vary with applied power. Thus, the flux obtained from such a source may depend on the material used and the power applied. In spite of these variations, it is still possible to determine locations and power requirements to produce films of uniform thickness from an array of such sources.

The apparatus of FIG. 8 may be employed, for example, in connection with operation of the apparatus of FIGS. 2-7. The apparatus of FIG. 8 may be instantiated locally at the corresponding device (e.g., in the control panel 142 of the chamber 132), or may be instantiated at another location and remotely access and/or control the chamber. Thus, in some embodiments, the apparatus may be instantiated, for example, at a network device, server, proxy, or the like. Alternatively, embodiments may be employed in a distributed fashion on a combination of devices. Accordingly, some embodiments of the present invention may be embodied wholly at a single device (e.g., the control panel 40) or by devices in a client/server relationship. Furthermore, it should be noted that the devices or elements described below may not be mandatory and thus some may be omitted in certain embodiments.

An example of a coating applied to a substrate (a telescope minor) using six magnetron sources is described below. The apparatus and notation for the following example is consistent with the exemplary embodiment depicted in FIG. 2 except, as noted above, the following example employs six sources instead of the three depicted in FIG. 2.

The substrate in the present example has an outer diameter D_{O} of 840 cm and an inner diameter D_{I} of 0 cm (i.e., there is no central opening in the mirror). An outer radius of the mirror R_{O} is therefore D_{O}/2=420 cm, and the inner radius Rᵢ is 0 cm.

Each of the sources (numbered 0 through 5) is provided at a height 60 cm above the surface of the substrate. The sources are arranged so that their centers are provided at a distance from the axis of rotation of the substrate (rₙ) and their radii (rₘₙ) are as follows:

TABLE 1
Distance and Radius of Sources

| rₙ | rₘₙ |
|---|---|
| r₀ = 48 cm | rₘ₀ = 10 cm |
| r₁ = 123 cm | rₘ₁ = 16 cm |
| r₂ = 195 cm | rₘ₂ = 16 cm |
| r₃ = 265 cm | rₘ₃ = 20 cm |
| r₄ = 340 cm | rₘ₄ = 20 cm |
| r₅ = 420 cm | rₘ₅ = 20 cm |

The power (Pn) of each source, and power density (pn) of each source (calculated from the power values below and size values above) are as follows:

TABLE 2
Power and Power Density for Sources

| Pn | pn |
|---|---|
| P0 = 2000 W | P0 = 6.366 W/cm² |
| P1 = 5750 W | p1 = 7.15 W/cm² |
| P2 = 7980 W | p1 = 9.922 W/cm² |
| P3 = 11730 W | p1 = 9.334 W/cm² |
| P4 = 16000 W | p1 = 12.732 W/cm² |
| P5 = 26000 W | p1 = 20.69 W/cm² |

The coating thickness tn(R) due to each source n at a radius R from the center of the mirror is then given by applying the above values in Equation 1, or:

$$\begin{matrix}t 0 ( R ) := {\int }_{0}^{2 \cdot π} {\int }_{0}^{rm 0} {\int }_{0}^{2 \cdot π} \frac{h {0}^{2} \cdot r \cdot p 0}{{[ h {0}^{2} + [ \begin{matrix}{( R \cdot cos ( Φ ) - ( r 0 + r \cdot cos ( Θ ) ) )}^{2} + \\ {( R \cdot sin ( Φ ) - r \cdot sin ( Θ ) )}^{2}\end{matrix} ] ]}^{2}} d Θ d r d Φ & Equation 4 \\ t 1 ( R ) := {\int }_{0}^{2 \cdot π} {\int }_{0}^{rm 1} {\int }_{0}^{2 \cdot π} \frac{h {1}^{2} \cdot r \cdot p 1}{{[ h {1}^{2} + [ \begin{matrix}{( R \cdot cos ( Φ ) - ( r 1 + r \cdot cos ( Θ ) ) )}^{2} + \\ {( R \cdot sin ( Φ ) - r \cdot sin ( Θ ) )}^{2}\end{matrix} ] ]}^{2}} d Θ d r d Φ & Equation 5 \\ t 2 ( R ) := {\int }_{0}^{2 \cdot π} {\int }_{0}^{rm 2} {\int }_{0}^{2 \cdot π} \frac{h {2}^{2} \cdot r \cdot p 2}{{[ h {2}^{2} + [ \begin{matrix}{( R \cdot cos ( Φ ) - ( r 2 + r \cdot cos ( Θ ) ) )}^{2} + \\ {( R \cdot sin ( Φ ) - r \cdot sin ( Θ ) )}^{2}\end{matrix} ] ]}^{2}} d Θ d r d Φ & Equation 6 \\ t 3 ( R ) := {\int }_{0}^{2 \cdot π} {\int }_{0}^{rm 3} {\int }_{0}^{2 \cdot π} \frac{h {3}^{2} \cdot r \cdot p 3}{{[ h {3}^{2} + [ \begin{matrix}{( R \cdot cos ( Φ ) - ( r 3 + r \cdot cos ( Θ ) ) )}^{2} + \\ {( R \cdot sin ( Φ ) - r \cdot sin ( Θ ) )}^{2}\end{matrix} ] ]}^{2}} d Θ d r d Φ & Equation 7 \\ t 4 ( R ) := {\int }_{0}^{2 \cdot π} {\int }_{0}^{rm 4} {\int }_{0}^{2 \cdot π} \frac{h {4}^{2} \cdot r \cdot p 4}{{[ h {4}^{2} + [ \begin{matrix}{( R \cdot cos ( Φ ) - ( r 4 + r \cdot cos ( Θ ) ) )}^{2} + \\ {( R \cdot sin ( Φ ) - r \cdot sin ( Θ ) )}^{2}\end{matrix} ] ]}^{2}} d Θ d r d Φ & Equation 8 \\ t 5 ( R ) := {\int }_{0}^{2 \cdot π} {\int }_{0}^{rm 5} {\int }_{0}^{2 \cdot π} \frac{h {5}^{2} \cdot r \cdot p 5}{{[ h {5}^{2} + [ \begin{matrix}{( R \cdot cos ( Φ ) - ( r 5 + r \cdot cos ( Θ ) ) )}^{2} + \\ {( R \cdot sin ( Φ ) - r \cdot sin ( Θ ) )}^{2}\end{matrix} ] ]}^{2}} d Θ d r d Φ & Equation 9\end{matrix}$$

These individual source contributions for

The thickness of the coating material on the substrate at a particular radius value R is given by the contribution of each source at that location:

t(R):=t0(R)+t1(R)+t2(R)+t3(R)+t4(R)+t5(R) Equation 10

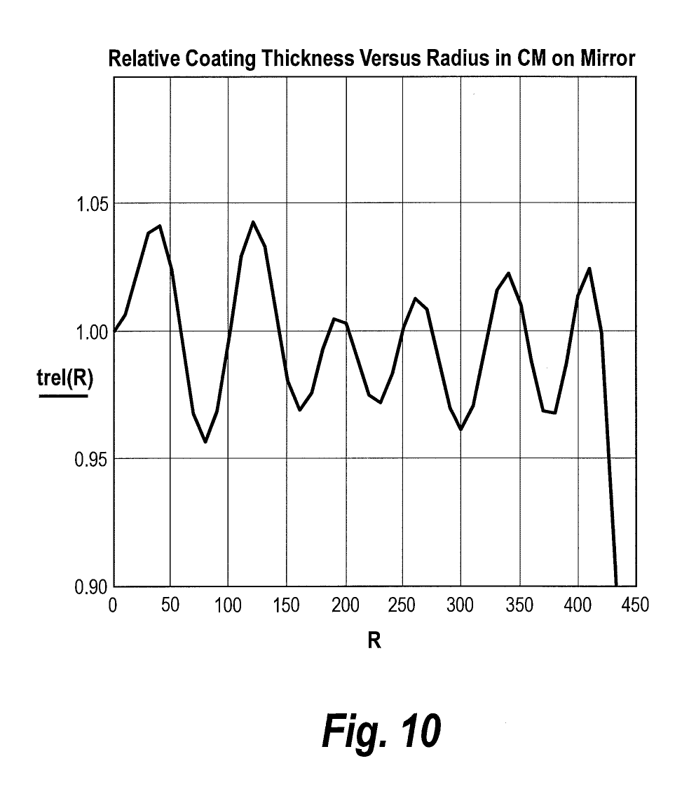

As noted above, the relative thickness trel(R) at a location a distance R from the center of the substrate, normalized to a the thickness at the center of the substrate, is given by Equation 3. Such a relative thickness for the present example for each value of R is depicted in FIG. 10.

As can be seen in FIG. 10, the relative thickness between the center of the substrate to the outer diameter of 420 cm varies by less than 5% in either direction. Thus, a substantially uniform coating thickness may be achieved.

In summary, according to exemplary embodiments, multiple sources may be provided in relative rotation to a substrate to generate a desired substantially uniform coating thickness on a substrate of any size.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe exemplary embodiments in the context of certain exemplary combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims.

Furthermore, as used herein, the term “or” is to be interpreted as a logical operator that results in true whenever one or more of its operands are true (i.e., a “non-exclusive or”). As used herein, operable coupling should be understood to relate to direct or indirect connection that, in either case, enables functional interconnection of components that are operably coupled to each other.

In cases where advantages, benefits or solutions to problems are described herein, it should be appreciated that such advantages, benefits and/or solutions may be applicable to some example embodiments, but not necessarily all example embodiments. Thus, any advantages, benefits or solutions described herein should not be thought of as being critical, required or essential to all embodiments or to that which is claimed herein. Although specific terms are employed herein, they are used in a generic and descriptive sense only and not for purposes of limitation.

1. An apparatus comprising:
a deposition chamber configured to receive a substrate; and
a plurality of deposition sources disposed a selectable distance away from the substrate, wherein the substrate is rotatable relative to the sources, or the sources are rotatable relative to the substrate.

2. The apparatus of claim 1, wherein the sources are coupled to a gantry elevated at the selectable distance above the substrate.

3. The apparatus of claim 2, wherein the gantry is rotatable in a continuous or oscillatory fashion relative to the substrate.

4. The apparatus of claim 1, wherein the substrate is rotatable in a continuous or oscillatory fashion relative to the sources.

5. The apparatus of claim 1, wherein the substrate and the sources are each rotatable.

6. The apparatus of claim 1, further comprising:
control circuitry configured to utilize information indicative of an emission pattern associated with each of the sources to adjust power to each of the sources during coating of the substrate via the sources.

7. The apparatus of claim 6, wherein the control circuitry is configured to further control rotation of the substrate or the sources and control environmental parameters in the deposition chamber.

8. The apparatus of claim 6, wherein the control circuitry is further configured to utilize information indicative of an emission pattern associated with each of the sources to adjust a distance between the sources and the substrate or a tilt angle of one or more of the sources relative to the substrate.

9. The apparatus of claim 1, wherein the deposition sources comprise:
magnetron sputter sources;
electron beam evaporation sources;
thermally heated sources;
chemical vapor deposition sources; or
ion beam deposition sources.

10. The apparatus of claim 1, wherein the control circuitry is further configured to coat the substrate to a substantially uniform thickness within a tolerance of between 1% and 5%.

11. A method comprising:
receiving information indicative of an emission pattern associated with each of a plurality of deposition sources disposed a selectable distance away from a substrate to be coated;
receiving information indicative of relative rotation between the substrate and the sources; and
determining, via processing circuitry, a power level to be applied to each of the sources during coating of the substrate via the sources based on the received information indicative of the emission pattern associated with each of the sources and the received information indicative of the relative rotation.

12. The method of claim 11, further comprising controlling each of the sources to achieve the determined power levels.

13. The method of claim 12, wherein the controlling causes the coating to be applied to the substrate at a substantially uniform thickness within a tolerance of between 1% and 5%.

14. The method of claim 11, further comprising determining an amount of tilt to be applied to at least one of the sources during coating of the substrate via the sources based on the received information indicative of the emission pattern associated with the source and the received information indicative of the relative rotation.

15. The method of claim 11, further comprising determining at least one environmental variable to be controlled during coating of the substrate based on the received information indicative of the emission pattern associated with each of the sources and the received information indicative of the relative rotation.

16. The method of claim 11, wherein the information indicative of the relative rotation describes a rotation of the substrate.

17. The method of claim 11, wherein the information indicative of the relative motion describes a rotation of the sources.

18. The method of claim 11, wherein the information indicative of the relative motion describes a rotation of both the substrate and the sources.

19. A non-transitory electronic device readable medium storing computer-readable instructions that, when executed by an electronic device, cause the electronic device to:
receive information indicative of an emission pattern associated with each of a plurality of deposition sources disposed a selectable distance away from a substrate to be coated;
receive information indicative of relative rotation between the substrate and the sources; and
determine, via processing circuitry, a power level to be applied to each of the sources during coating of the substrate via the sources based on the received information indicative of the emission pattern associated with each of the sources and the received information indicative of the relative rotation.

20. An apparatus, comprising:
a housing configured to receive a substrate;
a plurality of sources disposed a selectable distance away from the substrate for depositing a material thereon; and
control circuitry configured to utilize information indicative of an emission pattern associated with each of the sources to adjust power to each of the sources during coating of the substrate via the sources,
wherein the substrate and the plurality of sources are movable relative to each other.

21. The apparatus of claim 20, further comprising a support within the housing for supporting the substrate, wherein the support is rotatable with respect to the sources.

22. The apparatus of claim 21, further comprising a support within the housing for supporting the substrate, wherein the support is movable to vary a distance between the substrate and the sources.
